(19) United States
(12) Patent Application Publication
(10) Pub. No.: US 2025/0386729 A1
(43) Pub. Date: Dec. 18, 2025

(54) Energy Device and Superconducting Material

(71) Applicant: Steven BARANOWITZ, Wyncote, PA (US)

(72) Inventor: Steven BARANOWITZ, Wyncote, PA (US)

(21) Appl. No.: 18/878,191

(22) PCT Filed: Jun. 14, 2023
(86) PCT No.: PCT/US2023/025243

§ 371 Date: Dec. 23, 2024

Related U.S. Application Data
(60) Provisional application No. 63/355,747, filed on Jun. 27, 2022.
(60) Provisional application No. 63/430,072, filed on Dec. 5, 2022.

(51) Int. Cl. H10K 85/00

(52) U.S. Cl. CPC H10K 85/761

(57) ABSTRACT

This invention relates to a melanin derivate and process for its production. The invention further relates to the use of the product from the process disclosed herein in a multi-functional integrated energy conversion device comprising the melanin derivate. In accordance with the single example, Hephamelanin is produced from a process wherein melanin (from cuttlefish) has been purified by repeat centrifugation and washing (at least 3-10 times) and then subjected to thermal treatment at 200-850° C. under alternative vacuum or noble gas atmosphere conditions (and thereafter given the title Hephamelanin). The process also applies to all forms of melanin materials, including natural or synthetic alternatives. In embodiments when the source melanin is from naturally occurring sources (i.e. cuttlefish) the centrifugation/washing step is to remove unwanted impurities/proteins to achieve necessary purity prior to thermal treatment at the aforesaid temperature and atmosphere conditions. Synthetic alternative melanin sources may be used directly (such as other polydopamines), as their purity may already be satisfactory prior to thermal treatment without the need for any centrifugation steps. Hephamelanin also absorbs radiation, including the entire electromagnetic spectrum. Hephamelanin is remarkably hard and resists abrasion like a metal or synthetic polymer. Hephamelanin variants include starting with a synthetic or natural melanin and doping it with metal ions such as bismuth, copper, silver, etc. or other ions, which enhance its properties for various applications. The disclosure provides that Hephamelanin is as strong as metals and hard polymers, has superior abrasion resistance, heat resistance, tensile strength, and other highly desirable physical properties. It can be used in armour or shielding. It will protect against attack by physical agents and by radiation. It will absorb or reflect most types of radiation, including the entire electromagnetic spectrum. The energy absorbed from the radiation can be transduced to electricity. The present invention concerns an energy conversion and/or storage method and apparatus for providing electric power by employing several physical characteristics of melanin, Hephamelanin, and composite materials as disclosed herein, including the ability of such materials to transduce energy into electrical energy. The disclosure provides a multifunctional integrated energy conversion device comprising: at least one electric transducer comprising the Hephamelanin material as disclosed.

This International PCT application claims benefit of U.S. Ser. No. 63/355,747 filed Jun. 27, 2022 and 63/430,072 filed Dec. 5, 2022, their entireties of which are incorporated herein by reference.

### BACKGROUND

Energeon is a multifunctional integrated energy conversion device designed to operate primarily in outer space. It performs all the following activities with multiple forms of energy: absorption, transduction, transmission, and storage.

The foundation of Energeon is a single “basic material” that has many chemical and physical functions and characteristics, so that derivatives of this material are used in some degree for all of its critical functions. The disclosure provides that Hephamelanin also absorbs radiation, including the entire electromagnetic spectrum. It is remarkably hard and resists abrasion like a metal or synthetic polymer. An example of the basic material is melanin. Either synthetic melanin (made by organic or water-based synthesis) or natural melanin may be used.

The natural melanin may be dispersed in, for example, in water, deionized water, distilled water, and/or combinations thereof, and then centrifuged to remove some non-melanin proteins found in the raw natural material. The material is then placed in a vacuum furnace heated or in an alternative embodiment, it can be surrounded by a noble gas. The inventor calls the resulting formulation Hephamelanin, named after Hephaestus, the Greek god of blacksmiths and fire. The inventor has discovered that Hephamelanin is superconducting. Hephamelanin can preferably be used at temperatures ranging from slightly above absolute zero to room temperature. Most preferably it will be used in the range of liquid nitrogen temperatures (e.g., about 77° Kelvin), or in the range of the temperature of outer space, which is about 4° Kelvin. This temperature is most common in interstellar space, where the light of local stars does not create heat.

The disclosure provides that Hephamelanin also absorbs radiation, including the entire electromagnetic spectrum. It is remarkably hard and resists abrasion like a metal or synthetic polymer. Hephamelanin variants include starting with a synthetic or natural melanin and doping it with metal ions such as bismuth, copper, silver, etc. or other ions, which enhance its properties for various applications.

The disclosure provides that Hephamelanin is as strong as metals and hard polymers, has superior abrasion resistance, heat resistance, tensile strength, and other highly desirable physical properties. It can be used in armor or shielding. It will protect against attack by physical agents and by radiation. It will absorb or reflect most types of radiation, including the entire electromagnetic spectrum. The energy absorbed from the radiation can be transduced to electricity.

In another embodiment, derivatives of the basic material (for example, melanin), which are superconducting, such as Hephamelanin, are used in a multifunctional integrated energy conversion device, referred to an Energeon, which is, for example, designed to operate primarily in outer space. It performs all the following activities with multiple forms of energy: absorption, transduction, transmission, and storage. The foundation of Energeon is a single “basic material” that has many chemical and physical functions and characteristics, so that derivatives of this material are used in some degree for all of its critical functions.

For the transmission of energy and especially electricity, Energeon uses derivatives of the basic material (for example, melanin), which are superconducting. The temperature in outer space is about 4° K, and there are many substances which are superconducting at this temperature, including as disclosed herein, formulations and derivatives of melanin. Outer space also is a vacuum which avoids agents which can degrade superconducting materials on earth such as including oxygen and other gases.

Derivatives of the basic material are able to absorb many types of energy, including light, heat, radiation, sound waves, pressure waves, and vibrations. For instance, melanin is known to absorb light and convert it to electrical energy by photoconductivity (Meredith and Sarna, 2006), heat through pyroelectricity (Li et al., 2014) or thermoelectricity, pressure through piezoelectricity, sound, radiation particles and waves, and sound (Meredith and Sarna, 2006). The basic material or its derivatives can transduce all these input sources of energy into electrical energy and store or output electrical energy, and other types of energy such as light, and sound.

The basic material can transmit energy, preferably, by superconductivity. For example, superconductivity using melanin alloys has already been demonstrated with melanin doped to other materials (Qaid et al., 2022).

The base material or its derivatives can also efficiently store energy. For instance, melanin has been configured to form supercapacitors or batteries. (See McGinness, 1982; Kim et al., 2013; Gouda et al., 2019; Kumar et al., 2016).

Energeon is also capable of storing information. The basic material or its derivatives take advantage of an unusual suite of electronic and chemical properties, such as in melanin, which have already been demonstrated to store information. Computing capacities are also present due to the semiconductor (switching and memory) capacities (Chen et al., 2021; Meredith, 2006) and transistor properties (Sheliakina et al., 2018).

Energeon is mostly solid-state with few or no moving parts that would generate friction and to therefore degrade its performance.

Although Energeon performs optimally in interstellar space, variations of it can be adapted to function in near space and on earth. For instance, the cold of outer space can be simulated by artificial environments on earth to permit superconductive electricity transmission. A wide variety of commercial and scientific equipment requires a reliable source of electrical power, either stored or generated, for operation in remote locations not connected to electrical power distribution networks. Some of the known terrestrial uses for such power sources include transmitters, relays, boosters, unmanned weather stations, environmental monitoring stations, radar arrays in antarctic/arctic/other remote areas, submarine cable boosters and the like. Aerospace and outerspace applications are even more in need of reliable sources of electrical power. Chemical batteries are well known sources of stored power but often cannot provide sufficient stored energy and power to meet mission needs. In such cases, batteries must be supplemented by solar or other energy conversion devices.

In order to secure electricity in remote places where power generation by a solar cell is difficult, there is a case where a method in which, for example, Energeon can absorb light and convert it to electrical energy by photoconductivity, heat through pyroelectricity or thermoelectricity, pressure through piezoelectricity, sound, radiation particles and waves, and sound. The basic material or its derivatives can transduce all these input sources of energy into electrical energy and store or output electrical energy, and other types of energy such as light, and sound heat energy is secured and electricity is secured by the conversion.

In the generator of the present invention and the method for using the same, a Hephamelanin material and/or derivative thereof converts to energy to electricity. Particularly, in the case of using the generator of the present disclosure in a space probe, it is possible to control the energy conversion at a timing where the space probe sufficiently rises away from the ground. Therefore, the safety management of the space probe becomes dramatically easier, and it is possible to dramatically improve the flexibility of space exploration.

Accordingly, it is an object of the present invention to provide an electrical power that offers a minimal system mass. It is a further object of the present invention to provide an electrical power whose operation is simple, compact, safe, robust and reliable.

It is yet another object of the present invention to provide an electrical power that offers an electric power to mass ratio and a relatively high operating temperature that permit the use of the power source in a wide variety of spacecraft and planetary surface systems. It also is an object of the present invention to provide an electrical power that offers minimal risk for a release of hazardous radioactive materials.

All references cited herein are incorporated herein by reference in their entireties.

### BRIEF SUMMARY

The present invention concerns an energy conversion and/or storage method and apparatus for providing electric power by employing several physical characteristics of melanin, Hephamelanin, and composite materials as disclosed herein, including the ability of such materials to transduce energy into electrical energy.

The disclosure provides a Hephamelanin material made by a process comprising: dispersing a basic material selected from the group consisting of natural melanin, synthetic melanin, and combinations thereof, in water; centrifuging the basic material; repeating step i) and ii) at least about 3 times, to form a purified basic material; placing the purified basic material in a vacuum furnace; and heating the purified basic material for at least 1.5 hours at temperatures ranging from about 200° C. to about 850° C., thereby forming a Hephamelanin material. The disclosure provides a Hephamelanin material made by a process comprising: dispersing a basic material selected from the group consisting of natural melanin, synthetic melanin, and combinations thereof in water; centrifuging the basic material; repeating step i) and ii) at least about 5 times, to form a purified basic material; placing the purified basic material in a furnace; surrounding the purified basic material with at least one noble gas; and heating the purified basic material for at least 1.5 hours at temperatures ranging from about 200° C. to about 850° C., thereby forming a Hephamelanin material. The disclosure provides a Hephamelanin material made by a process wherein the noble gas is selected from the group consisting of helium (He), neon (Ne), argon (Ar), krypton (Kr), xenon (Xe), radon (Rn), oganesson (Og), and combinations thereof. The disclosure provides a Hephamelanin material made by a process wherein step iii) is repeated at least about 4 times, at least about 5 times, at least about 6 times, at least about 7 times, at least about 8 times, at least about 9 times, or at least about 10 times. The disclosure provides a Hephamelanin material made by a process wherein the Hephamelanin material can absorb types of energy selected from the group consisting of light, heat, radiation, sound waves, pressure waves, vibrations, and combinations thereof. The disclosure provides a Hephamelanin material made by a process wherein energy absorbed by the Hephamelanin material is transduced to electricity. The disclosure provides a Hephamelanin material made by a process wherein light absorbed by the Hephamelanin material is converted to electricity by photoconductivity. The disclosure provides a Hephamelanin material made by a process wherein heat absorbed by the Hephamelanin material is converted to electricity through pyroelectricity. The disclosure provides a Hephamelanin material made by a process wherein heat absorbed by the Hephamelanin material is converted to electricity through thermoelectricity. The disclosure provides a Hephamelanin material made by a process wherein pressure absorbed by the Hephamelanin material is converted to electricity through piezoelectricity. The disclosure provides a Hephamelanin material made by a process wherein sound absorbed by the Hephamelanin material is converted to electricity. The disclosure provides a Hephamelanin material made by a process wherein radiation particles and waves absorbed by the Hephamelanin material are converted to electricity. The disclosure provides a Hephamelanin material made by a process wherein the Hephamelanin material absorbs radiation, including the entire electromagnetic spectrum, and can convert this energy into electricity. The disclosure provides a Hephamelanin material made by a process wherein the Hephamelanin material or its derivatives can transduce input sources of energy into electrical energy and store or output electrical energy. The disclosure provides a Hephamelanin material made by a process wherein the Hephamelanin material can transmit energy, by superconductivity. The disclosure provides a Hephamelanin material made by a process wherein the Hephamelanin material or its derivatives can also efficiently store energy. The disclosure provides a Hephamelanin material made by a process wherein the has been configured to form supercapacitors or batteries.

The disclosure provides a Hephamelanin material made by a process wherein the Hephamelanin is hard and resists abrasion like a metal or synthetic polymer. The Hephamelanin material made by a process wherein the Hephamelanin material will protect against attack by physical agents and by radiation. The disclosure provides a Hephamelanin material made by a process wherein the Hephamelanin material is as strong as metals and hard polymers, has superior abrasion resistance, heat resistance, tensile strength, and other highly desirable physical properties. The disclosure provides a Hephamelanin material made by a process wherein the Hephamelanin material is used in armor or shielding.

The disclosure provides a process for forming a Hephamelanin material comprising the steps of: dispersing a basic material selected from the group consisting of natural melanin, synthetic melanin, and combinations thereof, in a water; centrifuging the basic material; repeating step i) and ii) at least about 5 times, to form a purified basic material; placing the purified basic material in a vacuum furnace; and heating the purified basic material for at least 1.5 hours at temperatures ranging from about 200°° C. to about 850° C., thereby forming a Hephamelanin material. The disclosure provides a process for forming a Hephamelanin material comprising the steps of: Dispersing a basic material selected from the group consisting of natural melanin, synthetic melanin, and combinations thereof, in water; centrifuging the basic material; repeating step i) and ii) at least about 5 times, to form a purified basic material; placing the purified basic material in a furnace; surrounding the purified basic material with at least one noble gas; and heating the purified basic material for at least 1.5 hours at temperatures ranging from about 200° C. to about 850° C., thereby forming a Hephamelanin material. The disclosure provides a process for forming a Hephamelanin material wherein the noble gas is selected from the group consisting of helium (He), neon (Ne), argon (Ar), krypton (Kr), xenon (Xe), radon (Rn), oganesson (Og), and combinations thereof. The disclosure provides a process for forming a Hephamelanin material wherein step iii) is repeated at least about 4 times, at least about 5 times, at least about 6 times, at least about 7 times, at least about 8 times, at least about 9 times, or at least about 10 times. The disclosure provides a process for forming a Hephamelanin material wherein the Hephamelanin material can absorb types of energy selected from the group consisting of light, heat, radiation, sound waves, pressure waves, vibrations, and combinations thereof. The process for forming a Hephamelanin material wherein energy absorbed by the Hephamelanin material is transduced to electricity. The disclosure provides a process for forming a Hephamelanin material wherein light absorbed by the Hephamelanin material is converted to electricity by photoconductivity. The disclosure provides a process for forming a Hephamelanin material wherein heat absorbed by the Hephamelanin material is converted to electricity through pyroelectricity. The disclosure provides a process for forming a Hephamelanin material wherein heat absorbed by the Hephamelanin material is converted to electricity through thermoelectricity. The disclosure provides a process for forming a Hephamelanin material wherein pressure absorbed by the Hephamelanin material is converted to electricity through piezoelectricity. The disclosure provides a process for forming a Hephamelanin material wherein sound absorbed by the Hephamelanin material is converted to electricity. The disclosure provides a process for forming a Hephamelanin material wherein radiation particles and waves absorbed by the Hephamelanin material are converted to electricity. The disclosure provides a process for forming a Hephamelanin material wherein Hephamelanin material absorbs radiation, including the entire electromagnetic spectrum, and can convert this energy into electricity. The disclosure provides a process for forming a Hephamelanin material wherein the Hephamelanin material or its derivatives can transduce input sources of energy into electrical energy and store or output electrical energy. The disclosure provides a process for forming a Hephamelanin material wherein the Hephamelanin material can transmit energy, by superconductivity. The disclosure provides a process for forming a Hephamelanin material wherein the Hephamelanin material or its derivatives can also efficiently store energy. The disclosure provides a process for forming a Hephamelanin material wherein the Hephamelanin material has been configured to form supercapacitors or batteries. The disclosure provides a process for forming a Hephamelanin material wherein the Hephamelanin material is hard and resists abrasion like a metal or synthetic polymer. The disclosure provides a process for forming a Hephamelanin material wherein the Hephamelanin material will protect against attack by physical agents and by radiation. The disclosure provides a process for forming a Hephamelanin material wherein the Hephamelanin material is as strong as metals and hard polymers, has superior abrasion resistance, heat resistance, tensile strength, and other highly desirable physical properties. The disclosure provides a process for forming a Hephamelanin material wherein the Hephamelanin material is used in armor or shielding.

The disclosure provides a multifunctional integrated energy conversion device comprising: at least one electric transducer comprising the Hephamelanin material as disclosed herein, wherein said Hephamelanin material can absorb types of energy selected from the group consisting of light, heat, radiation, sound waves, pressure waves, vibrations, and combinations thereof, and convert the energy to electrical energy; optionally, an energy gathering element; optionally, electrical energy storage elements such as supercapacitors or batteries; optionally, electrical energy output elements; optionally control elements; wherein said electric transducer produces electric energy in response to the energy. The disclosure provides a multifunctional integrated energy conversion device which is mostly solid-state with few or no moving parts that would generate friction and to therefore degrade its performance. The disclosure provides a multifunctional integrated energy conversion device wherein the Hephamelanin material can absorb types of energy selected from the group consisting of light, heat, radiation, sound waves, pressure waves, vibrations, and combinations thereof. The disclosure provides a multifunctional integrated energy conversion device wherein energy absorbed by the Hephamelanin material is transduced to electricity. The disclosure provides a multifunctional integrated energy conversion device wherein light absorbed by the Hephamelanin material is converted to electricity by photoconductivity. The disclosure provides a multifunctional integrated energy conversion device wherein heat absorbed by the Hephamelanin material is converted to electricity through pyroelectricity. The disclosure provides a multifunctional integrated energy conversion device wherein heat absorbed by the Hephamelanin material is converted to electricity through thermoelectricity. The disclosure provides a multifunctional integrated energy conversion device wherein pressure absorbed by the Hephamelanin material is converted to electricity through piezoelectricity. The disclosure provides a multifunctional integrated energy conversion device wherein sound absorbed by the Hephamelanin material is converted to electricity. The disclosure provides a multifunctional integrated energy conversion device wherein radiation particles and waves absorbed by the Hephamelanin material are converted to electricity. The disclosure provides a multifunctional integrated energy conversion device wherein Hephamelanin material absorbs radiation, including the entire electromagnetic spectrum, and can convert this energy into electricity. The disclosure provides a multifunctional integrated energy conversion device wherein the Hephamelanin material or its derivatives can transduce input sources of energy into electrical energy and store or output electrical energy. The disclosure provides a multifunctional integrated energy conversion device wherein the Hephamelanin material can transmit energy, by superconductivity. The disclosure provides a multifunctional integrated energy conversion device wherein the Hephamelanin material or its derivatives can also efficiently store energy. The disclosure provides a multifunctional integrated energy conversion device wherein the Hephamelanin material has been configured to form supercapacitors or batteries. The disclosure provides a multifunctional integrated energy conversion device designed to operate primarily in outer space. The disclosure provides a multifunctional integrated energy conversion device wherein the Hephamelanin material is superconducting. The disclosure provides a multifunctional integrated energy conversion device which performs all the following activities with multiple forms of energy: absorption, transduction, transmission, and storage. The disclosure provides a multifunctional integrated energy conversion device which is also capable of storing information. The disclosure provides a multifunctional integrated energy conversion device which provides electrical energy to electrical power distribution networks. The disclosure provides a multifunctional integrated energy conversion device which provides electrical energy for terrestrial uses for such power sources include transmitters, relays, boosters, unmanned weather stations, environmental monitoring stations, radar arrays in antarctic/arctic/other remote areas, submarine cable boosters and the like. The disclosure provides a multifunctional integrated energy conversion device which provides electrical energy for Aerospace and outerspace applications. The disclosure provides a multifunctional integrated energy conversion device which can absorb light and convert it to electrical energy by photoconductivity, heat through pyroelectricity or thermoelectricity, pressure through piezoelectricity, sound, radiation particles and waves, and sound. The disclosure provides a multifunctional integrated energy conversion device wherein the Hephamelanin material or its derivatives can transduce input sources of energy into electrical energy and store or output electrical energy, and other types of energy such as light, and sound heat energy is secured, and electricity is secured by the conversion.

### BRIEF DESCRIPTION OF THE DRAWINGS

The invention will be described in conjunction with the following drawings in which like reference numerals designate like elements and wherein:

FIG. 1 is a diagram of the functions performed by the Energeon device.

FIG. 2 is an example of the exterior of an Energeon device.

FIG. 3 is an example of the interior of an Energeon device, as a cut-out diagram.

### DETAILED DESCRIPTION

As used herein, the term “about” when used in conjunction with a stated numerical value or range has the meaning reasonably ascribed to it by a person skilled in the art, i.e., denoting somewhat more or somewhat less than the stated value or range.

To the extent that the term “include,” “have,” or the like is used in the description or the claims, such term is intended to be inclusive in a manner similar to the term “comprise” as “comprise” is interpreted when employed as a transitional word in a claim.

The word “exemplary” is used herein to mean “serving as an example, instance, or illustration.” Any embodiment described herein as “exemplary” is not necessarily to be construed as preferred or advantageous over other embodiments.

The multifunctional integrated energy conversion device of the present disclosure may comprise a storage medium.

The melanin, Hephamelanin, and composite materials as disclosed herein, for example, the multifunctional integrated energy conversion devices as disclosed herein, are useful in many applications, including, but not limited to, next-generation thermoelectric power generation, superconductors, heat engines, such as otto cycle engines (e.g., car engines), diesel cycle engines, Brayton cycle engines (e.g., jet turbines), sterling cycle engines (e.g., NASA advance radioisotope sterling generator), Rankine cycle engines (e.g., classic steam power plant), microelectronics, including for microelectronics manufacturers interested in channeling heat or thermal isolation, insulation for consumer electronics, biomedicine, cryogenic or low temperature insulation, packaging, aerospace or space insulation, automotive insulation, heavy industry/equipment insulation, home insulation, petrochemical pipeline insulation, and new building construction and retrofits for improved energy efficiency.

### Melanin

As used here, the term “melanin” refers to melanins, melanin precursors, melanin analogs, melanin variants, melanin derivatives, and melanin-like pigments, unless the context dictates otherwise. The term “melanin-like” also refers to hydrogels with melanin-like pigmentation and quinoid electrophilicity. This electrophilicity can be exploited for facile coupling with biomolecules.

As used herein, the term “melanin analog” refers to a melanin in which a structural feature that occurs in naturally-occurring or enzymatically-produced melanins is replaced by a substituent divergent from substituents traditionally present in melanin. An example of such a substituent is a selenium, such as selenocysteine, in place of sulfur.

As used herein, the term “melanin derivative” refers to any derivative of melanin which is capable of being converted to either melanin or a substance having melanin activity. An example of a melanin derivative is melanin attached to a dihydrotrigonelline carrier such as described in Bodor, N., Ann. N. Y. Acad. Sci. 507, 289 (1987), which enables the melanin to cross the blood-brain barrier. The term melanin derivatives is also intended to include chemical derivatives of melanin, such as an esterified melanin.

As used herein, the term “melanin variant” refers to various subsets of melanin substances that occur as families of related materials. Included in these subsets, but not limited thereto, are:

(1) Naturally occurring melanins produced by whole cells that vary in their chemical and physical characteristics; (2) Enzymatically produced melanins prepared from a variety of precursor substrates under diverse reaction conditions; (3) Melanin analogs in which a structural feature that occurs in (1) or (2) above is replaced by an unusual substituent divergent from the traditional; and (4) Melanin derivatives in which a substituent in a melanin produced in (1), (2) or (3) above is further altered by chemical or enzymatic means.

As used herein, the term “Melanin-like substances” refers to heteropolymers of 5-6-dihydroxyindole and 5-6-dihydroxyindole-2-carboxylic acid which have one or more properties usually associated with natural melanins, such as UV absorption or semiconductor behavior.

The melanins comprise a family of biopolymer pigments. A frequently used chemical description of melanin is that it is comprised of “heteropolymers of 5-6-dihydroxyindole and 5-6-dihydroxyindole-2-carboxylic acid” (Bettinger et al., 2009). Melanins are polymers produced by polymerization of reactive intermediates. The polymerization mechanisms include, but are not limited to, autoxidation, enzyme-catalyzed polymerization and free radical initiated polymerization. The reactive intermediates are produced chemically, electrochemically, or enzymatically from precursors. Suitable enzymes include, but are not limited to, peroxidases, catalases, polyphenol oxidases, tyrosinase, tyrosine hydroxylases, and laccases. The precursors that are connected to the reactive intermediates are hydroxylated aromatic compounds. Suitable hydroxylated aromatic compounds include, but are not limited to 1) phenols, polyphenols, aminophenols and thiophenols of aromatic or polycyclicaromatic hydrocarbons, including, but not limited to, phenol, tyrosine, pyrogallol, 3-aminotyrosine, thiophenol and α-naphthol; 2) phenols, polyphenols, aminophenols, and thiophenols of aromatic heterocyclic or heteropoly cyclic hydrocarbons such as, but not limited to, 2-hydroxypyrrole,4-hydroxy-1,2-pyrazole, 4-hydroxypyridine, 8-hydroxyquinoline, and 4,5-dihydroxybenzothiazole.

The term melanin includes naturally occurring melanin polymers as well as melanin analogs as defined below. Naturally occurring melanins include eumelanins, phaeomelanins, neuromelanins and allomelanins.

As used here, the term “melanin” refers to melanins, melanin precursors, melanin analogs, melanin variants, melanin derivatives, melanin-like pigments, and/or melanosomes, unless the context dictates otherwise. The term “melanin-like” also refers to hydrogels with melanin-like pigmentation and quinoid electrophilicity. This electrophilicity can be exploited for facile coupling with biomolecules.

As used herein, the term “melanin analog” refers to a melanin in which a structural feature that occurs in naturally-occurring or enzymatically-produced melanins is replaced by a substituent divergent from substituents traditionally present in melanin. An example of such a substituent is a selenium, such as selenocysteine, in place of sulfur.

As used herein, the term “melanin derivative” refers to any derivative of melanin which is capable of being converted to either melanin or a substance having melanin activity. An example of a melanin derivative is melanin attached to a dihydrotrigonelline carrier such as described in Bodor, N., Ann. N.Y. Acad. Sci. 507, 289 (1987), which enables the melanin to cross the blood-brain barrier. The term melanin derivatives is also intended to include chemical derivatives of melanin, such as an esterified melanin.

As used herein, the term “melanin variant” refers to various subsets of melanin substances that occur as families of related materials. Included in these subsets, but not limited thereto, are:
(1) Naturally occurring melanins produced by whole cells that vary in their chemical and physical characteristics;
(2) Enzymatically produced melanins prepared from a variety of precursor substrates under diverse reaction conditions;
(3) Melanin analogs in which a structural feature that occurs in (1) or (2) above is replaced by an unusual substituent divergent from the traditional; and
(4) Melanin derivatives in which a substituent in a melanin produced in (1), (2) or (3) above is further altered by chemical or enzymatic means.

As used herein, the term “Melanin-like substances” refers to heteropolymers of 5-6-dihydroxyindole and 5-6-dihydroxyindole-2-carboxylic acid which have one or more properties usually associated with natural melanins, such as UV absorption or semiconductor behavior.

### Melanin Sources

Melanin and Melanin-like compounds can be obtained:
by extraction and purification from natural sources, e.g. cephalopods such as cuttlefish (e.g. Sepia) or squid (e.g. Loligo), bird feathers (e.g. from species with black strains such as Silkie chickens);
by chemical synthesis, whether water or non-water based e.g. (Deziderio, 2004) (daSilva et al., 2004; Lawrie et al., 2008; Pezzella et al., 2006);
by electrochemical synthesis, e.g. (Meredith et al., 2005);—by bioreactors created by utilization of natural or genetically altered bacteria, fungi, lichens, or viruses e.g.(della-Cioppa, 1998).

Cephalopod inks are natural composites of melanin with other materials, including peptidoglycans, amino acids, proteins, metals, and chemicals and enzymes (such as tyrosinase) which are involved in the synthesis of melanin, and other materials. Cephalopod inks include cuttlefish (such as Sepia), squid, and octopus inks. There is some variation among different species of the percentages of these components. Reports of cephalopod ink components include: Derby, C.D. 2014 Cephalopod Ink: Production, Chemistry, Functions and Applications Marine Drugs 12, 2700-2730; doi:10.3390/md12052700, and Magarelli M, Passamonti P, Renieri C. 2010. Purification, characterization and analysis of sepia melanin from commercial sepia ink (Sepia Officinalis). Rev CES Med Vet Zootec; Vol 5 (2): 18-28.

### Melanin Manufacturing and Fabrication

Melanin and melanin-like compounds can be manufactured as particles, nanoparticles, dust, beads, or fibers that are woven or non-woven e.g. by methods as described by (Greiner and Wendorff, 2007), sheets e.g. (Meredith et al., 2005), films (daSilva et al., 2004), plates, bricks, chars, spheres, nodules, balls, graphite-like sheets and shards, liquids, gels, or solids (e.g. thermoplastic or thermoset), and by common chemical engineering molding and fabrication methods or custom methods. Sheets can range from one molecular layer to several millimeters. Fibers can range from nanometers to several millimeters.

The melanin material may be natural or synthetic, with natural pigments being extracted from plant and animal sources, such as squid, octopus, mushrooms, cuttlefish, and the like. In some cases, it may be desirable to genetically modify or enhance the plant or animal melanin source to increase the melanin production. Melanins are also available commercially from suppliers.

The following procedure describes an exemplary technique for the extraction of melanin from cuttlefish (Sepia Officinalis). 100 gm of crude melanin are dissected from the ink sac of 10 cuttlefish and washed with distilled water (3×100 ml). The melanin is collected after each wash by centrifugation (200×g for 30 minutes). The melanin granules are then stirred in 800 ml of 8 M Urea for 24 hours to disassemble the melanosomes. The melanin suspension is spun down at 22,000×g for 100 minutes and then washed with distilled water (5×400 ml). The pellet is washed with 50% aqueous DMF (5×400 ml) until a constant UV baseline is achieved from the washes. Finally, the pellet is washed with acetone (3×400 ml) and allowed to air dry.

Synthetic melanins may be produced by enzymatic conversion of suitable starting materials, as described in more detail hereinbelow. The melanins may be formed in situ within the porous particles or may be performed with subsequent absorption into the porous particles.

Suitable melanin precursors include but are not limited to tyrosine, 3,4-dihydroxy phenylalanine (dopa), D-dopa, catechol, 5-hydroxyindole, tyramine, dopamine, m-aminophenol, oaminophenol, p-aminophenol, 4-aminocatechol, 2-hydroxyl-1,4-naphthaquinone (henna), 4-methyl catechol, 3,4-dihydroxybenzylamine, 3,4-dihydroxybenzoic acid, 1,2-dihydroxynaphthalene, gallic acid, resorcinol, 2-chloroaniline, p-chloroanisole, 2-amino-p-cresol, 4,5-dihydroxynaphthalene 2,7-disulfonic acid, o-cresol, m-cresol, p-cresol, and other related substances which are capable of being oxidized to tan, brown, or black melanin-like compounds capable of absorbing ultraviolet radiation when incorporated in the polymeric particle matrix of the present disclosure. Combinations of precursors can also be used.

The melanin precursor is dissolved in an aqueous solution, typically at an elevated temperature to achieve complete solution. A suitable amount of the enzyme tyrosinase (EC 1.14.18.1) is added to the solution, either before or after the melanin precursor. The concentration of tyrosinase is not critical, typically being present in the range from about 50 to about 5000 U/ml. The solution is buffered with an acetate, phosphate, or other suitable buffer, to a pH in the range from about 3 to 10, usually in the range from about 5 to 8, more usually being about 7. Melanin like pigments can be obtained using suitable precursors even in the absence of an enzyme just by bubbling oxygen through a solution of a precursor for an adequate period of time. Melanin material may be obtained by treatment of, e.g, cuttlefish ink or squid ink in a microwave, optionally with mixing. The inventor has found that microwaving can be used for the preparation of melanin formulations. The compositions and methods as disclosed herein may be produced and practiced using a variety of heating techniques, such as, for example, infrared heating, microwave heating, convection heating, laser heating, sonic heating, or optical heating. For example, it was found that drying melanin in a microwave oven made possible the preparation of large amount of melanin from cuttlefish ink in a very short period of time. In an exemplary embodiment, cuttlefish ink at was placed at 40° C. in a conventional oven and required 18 days to reduce the material to 40% of its original weight. In a 900 watt microwave oven, the same degree of drying was achieved in 12 minutes.

The disclosure provides a method for formulation of melanin by applying a hydraulic press to melanin partially dried in a microwave oven. In exemplary embodiments, hydraulic presses for this use may range in capacity from, for example, about 1 ton/sq. in. to about 500 tons/in2 approximately. The disclosure provides a method wherein the hydraulic press applies compression of approximately 500 tons/in2. In an exemplary embodiment, commercial cuttlefish ink was dried in a 900 watt microwave oven so that the product was 30% or 35% of the initial weight. A blender was used to mix and grind the melanin. A variety of formulations were made. In one formulation, the 30% preparation was mixed with 7% iron filings, and then the blender was used to mix again. In another formulation, 35% slabs were alternated with 30% slabs to create a layered composite. Each formulation was subjected to compression in a 20 ton/in2 hydraulic press for about 20 minutes. Because the platen was approximately 3.5 in2, it is estimated that a force of approximately 3265 pounds/sq. in. was exerted on each sample formulation.

The disclosure provides for the use of formulations of melanin produced by, for example, microwaving and hydraulic press compression. In an exemplary embodiment, two slabs of melanin were produced by placing cuttlefish ink at 40° C. in a conventional oven and dried for 18 days to reduce the material to 40% of its original weight. In an alternative embodiment, cuttlefish ink was placed in a 900 watt microwave oven, and dried for 12 minutes to form two slabs. Each slab was approximately 3.5 in square. One slab was 1 inch thick and 1 slab was 0.5 in. thick . . .

The disclosure provides for the use of elemental metals mixed with melanin to create new formulations of melanin with novel properties. The metals may be, for example, iron, copper, zinc, magnesium, manganese, bismuth, calcium, enamel, cesium, radium, strontium, thorium, uranium, or combinations thereof. In an exemplary embodiment, elemental iron was mixed with melanin in the form of dried cuttlefish ink resulted in unexpected hardness of the material while it remains somewhat flexible. Under scanning electron microscopy it was demonstrated that the new formulation of melanin had organized into stacks of lamellae, which appeared to be composed of melanosomes. This is an entirely novel finding since, although metal ions are known to bind to the melanin, it does not appear that anyone has experimented with or reported that elemental iron can bind. This new disclosure is based on the finding that iron and other elemental metals including, for example, copper, zinc, magnesium, manganese, bismuth, calcium, enamel, cesium, radium, strontium, thorium, or uranium, can bind to melanin and organize it in novel ways which confer upon it new properties. For instance, the new properties conferred will include enhanced hardness, stiffness, impact resistance, electrical conductivity, capacitance, semiconductor properties, and enhanced ability to absorb radiation including x-ray and gamma ray.

In an exemplary embodiment, cuttlefish ink was dried using a microwave oven to 40% of its original weight. Iron filings were added so that they comprised 0.5% of the final formulation. The material felt harder than a similar sample without the 0.5% iron filings. Scanning electron microscopy revealed multiple areas where sharply defined lamellae with 90° corner angles were seen in stacks.

The disclosure provides a practical method for formulating melanin to be placed into pharmaceutical or dietary supplement capsules, and other containers. A novel method was developed to enable formulation of melanin (e.g., from cephalopod ink) into capsules or other containers for pharmaceutical, dietary supplement, and other uses. In an exemplary embodiment, cuttlefish ink was dried using a microwave oven to 40% of its original weight. Cab-O-Sil, a pharmaceutical preparation of the excipient micronized silicon dioxide, was mixed to comprise 40% of the final mixture with the 40% dried cuttlefish ink. This mixture was placed in a hard size zero pharmaceutical capsule. After seven days that the capsule became weak and flaccid and would be unsuitable for use. When the mixture of silicon dioxide and cuttlefish ink was dried for several days in a conventional oven at 40° C., then placed in the capsule and observed, the capsule remained intact and is suitable for human and animal use.

In some embodiments, melanins are incorporated into other materials and used for many useful applications, such as:
1. Melanin and melanin-like compounds can be incorporated into: polymers, metals, salts, ceramics of many types, clothing, construction materials, existing armor materials including Kevlar and ceramics, other natural materials or their synthetic mimics, materials for implantation into human or mammalian living beings.
2. A small percentage of melanin confers new or improved properties on resultant material: Another aspect of the present disclosure is that small amounts of melanin and of melanin like substances will impart to a mixture of melanin with other substances, such as a matrix or polymer, properties which are unexpected. Generally, 1 to 5% of melanin will impart desired properties to a mixture or composite, whereas small incremental improvement in properties will be gained by increasing up to 35%. In exemplary embodies as disclosed herein, melanin may be present at about 1%, about 2%, about 3%, about 4%, about 5%, about 6%, about 7%, about 8%, about 9%, about 10%, at a range of about 1% to about 10%, at a range of about 2% to about 8%, at a range of about 3% to about 7%, at a range of about 1% to about 4%, at a range of about 2% to about 5%.

Examples of such unexpected properties are resistance to ultraviolet light, radiation, heat, flame, chemical agents and toxins, biological agents and toxins, and to abrasion.
3. Hydration effects and control: It is another aspect of the present disclosure that the control and maintenance of hydration of melanin and melanin like substances (or non-water solvent or matrix concentration for melanins made from organic solvents) is critical for the applications described above, including armor and shielding. Published research describes the effect of hydration on electrical conductivity, and on the ability to absorb radiation from the electromagnetic spectrum. The present disclosure includes the aspect that when melanin or melanin-like substances are extracted or synthesized, manufactured or fabricated, incorporated in any way with other substances, whether by mixtures, impregnation, layering, compositing, that control and maintenance of desired levels of hydration (and non-water solvent concentration for melanins made from organic solvents) may be critical to achieving and preserving the desired combination of properties. Much of the published research on melanin in the biological, chemical, physics, and electronics literature reports work done using commercially available melanin from Sigma-Aldrich Corp. (St. Louis, Missouri) which is prepared using lyophilization, thus dehydrating it. The present disclosure includes recognition that for the purposes set forth in this disclosure, such as armor and shielding, hydration and control of hydration may be critical for the properties desired in the final material, and the use of highly desiccated or lyophilized melanin may in many instances be undesirable. However, in certain aspects of the disclosure, desiccated or lyophilized melanin may be appropriate.
4. Oxygenation effects and control: It is another aspect of the present disclosure that the control and maintenance of oxygenation, or of lack of access to oxygen, by incorporating melanin into materials that control this factor, or by restricting use to environments that control or restrict this factor, may be critical for certain characteristics to be achieved for shielding, armor, flame retardancy, heat resistance, and cold resistance.
5. Incorporation methods for melanin into other materials includes, for example: mixtures, covalent or non-covalent binding, printing, stamping, electrochemical deposition, metallic salt binding, adhering, and layering in composites. In certain embodiments, the compositions and methods of the disclosure may be produced or practiced using molding techniques such as transfer molding, resin film infusion, resin transfer molding, and structural reaction injection molding (SRIM). In certain embodiments, the compositions and methods of the disclosure may be produced or practiced using molding techniques such as a vacuum assisted resin transfer molding process (VARTM).

### Biological Polymers

The term “biological polymer” according to the disclosure, it is understood collagen and its derivatives, hyaluronic acid, its salts and its derivatives, alginates, synthetic polymers, elastin and biological polymers, and mixtures thereof. Preferably, the biological polymer may comprises compounds chosen from collagen, collagen of porcine origin, collagen of bovine origin, crosslinked collagens, hyaluronic acid, its salts and its derivatives, lactic acid polymers, methacrylate derivatives, calcium phosphate derivatives, polyacrylamides, polyurethanes, polyalkylimide gels, polyvinyl microspheres, silicones, silica (SiO2) polymers, and mixtures thereof.

Collagen is a fibrous protein, of approximately 300 kDa, which makes up the connective tissue in the animal kingdom. It may be of human or nonhuman origin, in particular of porcine or bovine origin. Collagen derivatives include, inter alia, crosslinked collagens.

The composites of the disclosure may be formed from a wide variety of polymers, including natural polymers such as carboxylmethylcellulose, cellulose acetate phthalate, ethylcellulose, methylcellulose, arabinogalactan, nitrocellulose, propylhydroxycellulose, and succinylated gelatin; and synthetic polymers such as polyvinyl alcohol, polyethylene, polypropylene, polystyrene, polyacrylamide, polyether, polyester, polyamide, polyurea, epoxy, ethylene vinyl acetate copolymer, polyvinylidene chloride, polyvinyl chloride, polyacrylate, polyacrylonitrile, chlorinated polyethylene, acetal copolymer, polyurethane, polyvinyl pyrrolidone, poly(p-xylene), polymethylmethacrylate, polyvinyl acetate, polyhydroxyethyl methacrylate, and combinations thereof.

### Composites

Process aids and modifiers are materials commonly used to facilitate polymer fabrication, to help compatibilize the mixture of polymers, ceramics, and other additives, and the like, to increase fire resistance, or to modify other properties, other than primary ballistic protection properties. Any of these materials that are desirable for fabricating or using the new lightweight melanin, Hephamelanin, and composite materials as disclosed herein may be incorporated into the current disclosure, including but not limited to materials such as silicones, phthalates, bromides, and the like.

Other additives, present in amounts not exceeding 10% by weight, if any, may also be included. These materials may include, but are not limited to adhesion aides, colorants, fibers (carbon, polyaramid, polyethylene, etc.), fillers (talc, sand, microballoons) that further serve to modify the process-ability, stability, durability, or appearance of the objective ballistic protection materials.

Any suitable ceramic materials may be used in the composite composition in accordance with the current disclosure. In one embodiment the ceramic powders or particles may be selected from the group consisting of alumina, boron carbide, boron nitride, mullite, silica, silicon carbide, silicon nitride, magnesium boride, multi-walled carbon nanotubes, single walled carbon nanotubes, group IVB, VB and VIB metal sulfide nanotubes, titanium boride, titanium carbide, and diamond.

The current disclosure is also directed to methods of preparing ballistic protection materials. In one embodiment, the ballistic protection material is formed by a simple process of mixing the starting materials without melt processing prior to the final molding step. This simplifies the processing, as it is not necessary to undertake the possibly complicated step of melt processing with its accompanying difficulties in dispersion and equipment wear.

Although such a simple mixing process may be used, other processes for forming the ballistic protection material of the current disclosure can also be utilized. These include melt compounding, in which the ceramic and the polymer are intimately mixed while the polymer is in the molten state. In this embodiment the mixing can be done in any suitable standard machinery such as single and twin-screw extruders (both co- and counter-rotating), Henschel mixers, cokneaders, etc. An additional technique that can be used is solvent mixing in which the ceramic and the polymer are mixed while the polymer is dissolved in the appropriate solvent. In such an embodiment any suitable solvent may be utilized.

The current disclosure is also directed to articles made with the ballistic protection material in accordance with the above processes. Ballistic protection materials of the present disclosure may be fabricated into any suitable article, including but not limited to sheets, slabs, disks, or more complex shapes, of varying thicknesses and sizes.

Using such construction techniques, the ballistic protection materials of the present disclosure may be used together with other ballistic materials, including but not limited to woven ballistic fabrics (such as but not limited to polyaramid or polyethylene fabrics), metals, ceramics, and the like to form ballistic protection articles, such as, for example, helmets, sheets or panels, or body armor. In another example, body armor using the inventive material may be fabricated by first forming a woven fiber vest containing pockets then sewing flat or curved panels or tiles comprising the composite into the pockets. The sheets or panels may also be incorporated into a number of blast or ballistic shields or armor, such as, for example, blast/ballistics shields or armor for vehicles, aircraft and watercraft like cars, trucks, vans, personnel carriers, limousines, trailers, helicopters, cargo planes, rail cars, boats and ships; armor or blast/ballistic protection for small buildings, especially military command posts and mobile headquarters; armor or blast/ballistic protection for cargo containers; armor or blast/ballistic protection for equipment housing, such as, for example, computers, communications equipment; and generally mobile or stationary blast or ballistic protection panels.

In an embodiment, a structure is provided. The structure includes bonded alternating layers of at least a melanin material and at least one of a for example, fibrous sheet, a plastic sheet, a plastic plate, a ceramic sheet, a ceramic plate, and a multilayer ply, the multilayer ply comprising multiple fibrous sheets bonded together.

In another embodiment, a structure is provided. The structure includes alternating layers of melanin material wherein said layers are bonded to each other. In another embodiment, a structure is provided. The structure includes alternating layers of melanin material wherein said layers are joined to each other by an array of oriented nanostructures.

In yet another embodiment, a method for fabricating a melanin composite is provided. The method includes providing a first layer, the layer comprising at least a fibrous sheet or a multilayer laminate; applying a second layer to the first layer, the layer comprising an melanin material; applying a third layer to the second layer, the layer comprising another fibrous sheet or multilayer laminate; bonding or joining the first layer to the second layer; and bonding or joining the second layer to the third layer.

In another embodiment, a method for fabricating a melanin composite is provided. The method includes providing a first layer, the layer comprising at least a fibrous sheet or a multilayer laminate; applying a second layer to the first layer, the layer comprising a liquid-phase gel precursor; applying a third layer to the second layer, the layer comprising another fibrous sheet or multilayer laminate; bonding or joining the first layer to the second layer; and bonding or joining the second layer to the third layer.

In yet another embodiment, a method for fabricating a melanin composite is provided. The method includes providing two layers of melanin material and bonding the two layers together. In another embodiment, a method for fabricating a melanin composite is provided. The method includes providing a liquid-phase; forming a gel from the liquid-phase precursor; and optionally forming a second gel in contact with the first gel.

In an embodiment, a composition is provided. The composition includes melanin and non- melanin material and embedding the melanin material within the non-melanin material.

### Melanin Comprising Metal(s)

The disclosed method and materials take advantage of the fact that melanin is rather unique among armor-like materials in the following respect. Melanin has multiple functional groups (e.g., potential chemical binding locations) which can bind metals (Hong, L. and Simon, J.D., 2004, Photochem. Photobiol., 80:477-481). Many melanins have been demonstrated to possess at least four functional groups with regard to binding of metals: carboxyl, hydroxyl, phenolic, and amine. Metals can be linked, either covalently or non-covalently, absorbed, adsorbed, or chelated to specific functional groups with multiple beneficial effects including: strengthening the bonds between the atoms in the melanin polymer, adding properties of each individual metal dopant, such as density, weight, resistance to penetration or abrasion or radiation, etc. Additionally, some metals can bind to more than one functional group, and conditions such as pH and temperature can determine the preference of a metal for one or the other functional group.

It is known that once melanin and/or melanosomes are doped with a single metal, a second metal can be applied, in some instances, without dislodging the first metal (Hong, L. and Simon, J.D., 2007, J. Phys. Chem. B 111:7938-7947). As disclosed herein, more than one metal can simultaneously be used to dope melanin to enhance its impact-resistance and other protective properties. For instance, the metals bismuth and/or zinc can be linked to, for example, melanin's carboxyl group, and then copper could be linked to, for example, melanin's hydroxyl group. Also, some of the sites of one specific functional group can be loaded with one metal, while other unoccupied sites of the same functional group can then be loaded with a another metal. These sorts of manufacturing methods for improving the melanin's properties will lead to a variety of desirable properties regarding protective effect, which can be adjusted and tuned to particular applications.

### Utility and Characteristics

The following characteristics and functions for, for example, power generation, aerospace, armor, shielding and other applications can be achieved, in almost infinite variety of degrees and combinations, using the materials and methods as disclosed herein:

### Aerospace

The melanin, Hephamelanin, and composite materials as disclosed herein, for example in the multifunctional integrated energy conversion device as disclosed herein may also be particularly useful for electrical power generation. Some, but not all possible examples of power generation applications are now discussed.

The melanin, Hephamelanin, and composite materials as disclosed herein, for example in the multifunctional integrated energy conversion device as disclosed herein may be used for deep space power generation. Considerable effort by NASA and other agencies has established radioisotope thermoelectric generator (RTG) as the power source for deep space missions and therefore an integral component of space exploration. RTGs convert heat, generated by the radioactive decay of plutonium 239, into electricity and supply power to for example, deep space probes. The multifunctional integrated energy conversion device as disclosed herein can power generation and is uniquely valuable in deep space exploration since there is not a need for radioactive substances on board the spacecraft for deep space power generation.

The melanin, Hephamelanin, and composite materials as disclosed herein, for example in the multifunctional integrated energy conversion device as disclosed herein may be used for small-scale remote power generation. In addition, as electronic devices for spacecraft have become miniaturized and power needs have decreased, miniature power sources have become more important. A miniature or micro-device such as a sensor, an actuator, or electronic components require milliwatts of power at a few to several tens of volts. As devices shrink power needs also shrink and the development of power conversion devices in which milliwatts are provided with high specific power become important. Power generators such as the multifunctional integrated energy conversion device as disclosed herein fit this need.

The melanin, Hephamelanin, and composite materials as disclosed herein, for example in the multifunctional integrated energy conversion device may be used for low temperature power generation. The Hephamelanin material can produce power at low temperatures, with one leg of the power generator at temperatures below 77 K, a condition found in deep space.

The melanin, Hephamelanin, and composite materials as disclosed herein, for example in the multifunctional integrated energy conversion device as disclosed herein may be constructed using metals, ceramics, solders, conductive pastes, and/or electrically insulating features, depending on the device being made.

In certain applications as disclosed herein, the multifunctional integrated energy conversion device as disclosed herein may be utilized in a spacecraft which comprises a habitat module capable of rotating to provide an artificial gravity environment and a propulsion module capable of propelling the spacecraft through space.

In another aspect of the present disclosure, the melanin, Hephamelanin, and composite materials as disclosed herein, for example in the multifunctional integrated energy conversion device as disclosed herein may be utilized in a spacecraft which comprises an inflatable habitat module capable of rotating to provide an artificial gravity environment; a propulsion module capable of propelling the spacecraft through space; and a storage module, wherein the storage module and the propulsion module are contained in a center core of the spacecraft.

In yet another aspect of the present disclosure, the multifunctional integrated energy conversion device as disclosed herein may be utilized in a spacecraft for traveling through space which comprises an inflatable habitat module capable of rotating to provide an artificial gravity environment; a propulsion module capable of propelling the spacecraft through space; a storage module, wherein the storage module and the propulsion module are contained in a center core of the spacecraft; at least one radiator capable of radiating waste heat from the spacecraft; at least one solar panel capable of collecting solar energy; and at least three attitude thrusters capable of adjusting an attitude of the habitat module.

In a further aspect of the present disclosure, the melanin, Hephamelanin, and composite materials as disclosed herein, for example in the multifunctional integrated energy conversion device as disclosed herein may be utilized in a spacecraft which comprises an inflatable habitat module capable of rotating to provide an artificial gravity environment; a propulsion module capable of propelling the spacecraft through space; and a storage module, the propulsion module is located on a plane parallel to a circumferential plane of the habitat module.

In still a further aspect of the present disclosure, melanin, Hephamelanin, and composite materials as disclosed herein, for example in the multifunctional integrated energy conversion device as disclosed herein may be utilized in a method for space travel in a spacecraft which comprises providing an artificial gravity environment by rotating a habitat module at a velocity sufficient to create a gravitational force similar to a gravitational force on Earth; and propelling the spacecraft through space with a propulsion module.

### Energeon

Energeon is a multifunctional integrated energy conversion device designed to operate primarily in outer space. It performs all the following activities with multiple forms of energy: absorption, transduction, transmission, and storage.

The foundation of Energeon is a single “basic material” that has many chemical and physical functions and characteristics, so that derivatives of this material are used in some degree for all of its critical functions. The disclosure provides that Hephamelanin also absorbs radiation, including the entire electromagnetic spectrum. It is remarkably hard and resists abrasion like a metal or synthetic polymer. An example of the basic material is melanin. Either synthetic melanin (made by organic or water-based synthesis) or natural melanin may be used.

In another embodiment, derivatives of the basic material (for example, melanin), which are superconducting, such as Hephamelanin, are used in a multifunctional integrated energy conversion device, referred to an Energeon, which is, for example, designed to operate primarily in outer space. It performs all the following activities with multiple forms of energy: absorption, transduction, transmission, and storage. The foundation of Energeon is a single “basic material” that has many chemical and physical functions and characteristics, so that derivatives of this material are used in some degree for all of its critical functions.

For the transmission of energy and especially electricity, Energeon uses derivatives of the basic material (for example, melanin), which are superconducting. The temperature in outer space is about 4° K, and there are many substances which are superconducting at this temperature, including as disclosed herein, formulations and derivatives of melanin. Outer space also is a vacuum which avoids agents which can degrade superconducting materials on earth such as including oxygen and other gases.

Energeon is also capable of storing information. The basic material or its derivatives take advantage of an unusual suite of electronic and chemical properties, such as in melanin, which have already been demonstrated to store information. Computing capacities are also present due to the semiconductor (switching and memory) capacities (Chen et al., 2021; Meredith, 2006) and transistor properties (Sheliakina et al., 2018).

Energeon is mostly solid-state with few or no moving parts that would generate friction and to therefore degrade its performance.

Although Energeon performs optimally in interstellar space, variations of it can be adapted to function in near space and on earth. For instance, the cold of outer space can be simulated by artificial environments on earth to permit superconductive electricity transmission. A wide variety of commercial and scientific equipment requires a reliable source of electrical power, either stored or generated, for operation in remote locations not connected to electrical power distribution networks. Some of the known terrestrial uses for such power sources include transmitters, relays, boosters, unmanned weather stations, environmental monitoring stations, radar arrays in Antarctic/Arctic/other remote areas, submarine cable boosters and the like. Aerospace and outerspace applications are even more in need of reliable sources of electrical power. Chemical batteries are well known sources of stored power but often cannot provide sufficient stored energy and power to meet mission needs. In such cases, batteries must be supplemented by solar or other energy conversion devices.

In order to secure electricity in remote places where power generation by a solar cell is difficult, there is a case where a method in which, for example, Energeon can absorb light and convert it to electrical energy by photoconductivity, heat through pyroelectricity or thermoelectricity, pressure through piezoelectricity, sound, radiation particles and waves, and sound. The basic material or its derivatives can transduce all these input sources of energy into electrical energy and store or output electrical energy, and other types of energy such as light, and sound heat energy is secured, and electricity is secured by the conversion.

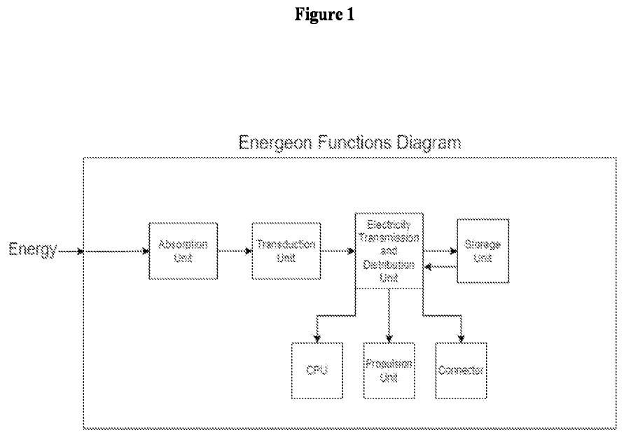

An exemplary diagrammatic representation of the functions of the Energeon device is provided in FIG. 1, which shows the flow of energy can be, for example, from an Absorption Unit to a Transduction Unit and to an Electricity Transmission and Distribution Unit and the energy can be stored in the Storage Unit, which can also provide energy to the Electricity Transmission Distribution Unit. The Electricity Transmission and Distribution Unit can connect to a Central Processing Unit (CPU), a Propulsion Unit, and/or a Connector Unit.

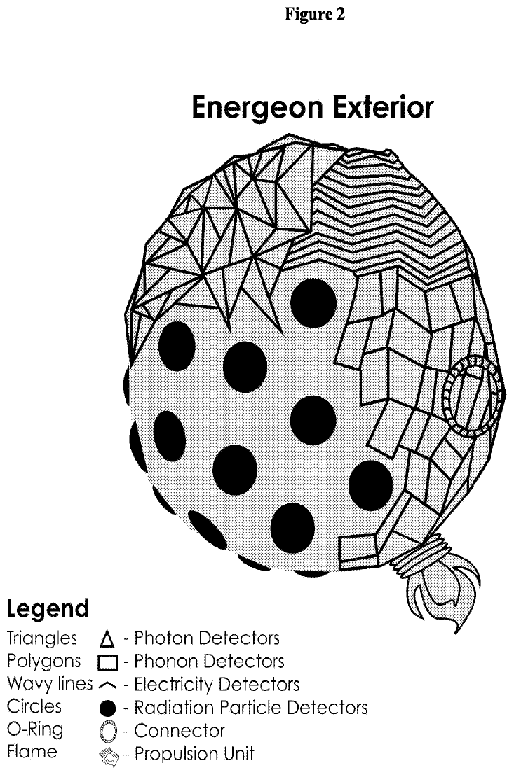

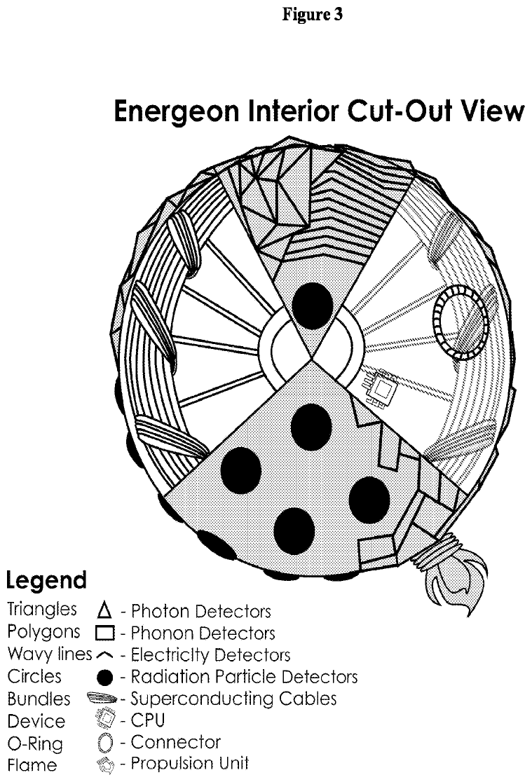

Referring to FIG. 2 which shows an example of the exterior of an Energeon device. The Energeon device has detectors for different types of energy, and these detectors can also absorb these types of energy. For example. Photons are units of light, Phonons are units of sound, heat, vibration, and pressure, Radiation particles include alpha and beta particles. There is also a connector units so individual devices can connect to form clusters. There is a propulsion unit so that the device can move. An exemplary interior of an Energeon device is shown as a cut-out diagram in FIG. 3, which shows the superconducting bundles lie just below the exterior, thus taking advantage of the cold of space at the exterior and transmitting electricity. There is an internal Central Processing Unit which manipulates information. In the center of the diagram is a circular storage unit, which is not labeled.

### Protection from Weapons

It is another aspect of the present disclosure that Hephamelanin, melanin and composite materials incorporating melanin can be used for shielding from biological, chemical, radiological and nuclear weapons.

It is another aspect of the present disclosure that Hephamelanin, melanin and composite materials incorporating melanin can be used for shielding from impact due to bullets or other projectiles or explosives, including shaped charges.

The current disclosure is directed to a ballistic protection material composition comprising one or more type of, e.g., ceramic powders or particles mixed with one or more type of melanin materials. In one embodiment, in addition to the melanin material, other polymeric materials may be further selected from the group consisting of rigid-rod polymers, semi-rigid-rod polymers, polyimides, polyetherimides, polyimideamides, polysulfones, epoxy resins, bismaleimide resins, bis-benzocyclobutene resins, phthalonitrile resins, polyaryletherketones, polyetherketones, liquid crystal polymers, oligomeric cyclic polyester precursors, polybenzbisoxazoles, polybenzbisthiazoles, polybenzbisimidazoles, acetylene endcapped thermosetting resins, PrimoSpire® polymers, polysulfones, polyaramides, poly-paraphenylene terephthalamide, polyamides, polycarbonates, polyethylenes, polyesters, polyphenols and polyurethanes.

In another embodiment, the composition further comprises one or more types of process aids, modifiers, colorants, fibers, adhesion promoters and fillers.

In still another embodiment, ceramic powders or particles are selected from the group consisting of alumina, boron carbide, boron nitride, mullite, silica, silicon carbide, silicon nitride, magnesium boride, multi-walled carbon nanotubes, single walled carbon nanotubes, group IVB, VB and VIB metal sulfide nanotubes, titanium boride, titanium carbide, and diamond.

In yet another embodiment, ceramic powders or particles provide 10% to 98% of the total mass, in a preferred embodiment the ceramic powders or particles provide 20% to 95% of the total mass, and in a most preferred embodiment the ceramic powders or particles provide at least 50% of the total mass.

In still yet another embodiment, ceramic powders or particles have particle size in the range of 10 nanometers to 100 microns; and in a preferred embodiment the ceramic powders or particles have particle size in the range of 100 nanometers to 10 microns.

In still yet another embodiment, the melanin material or materials provide 2% to 95% of the total mass, and in a preferred embodiment the melanin material or materials provide less than 50% of 1e total mass.

In still yet another embodiment, the ballistic protection materials are used together with other ballistic materials, including, but not limited to woven ballistic fabrics (such as but not limited to polyaramid or polyethylene fabrics), metals, ceramics, and the like. In still yet another embodiment, the ballistic protection materials are incorporated into an article selected from the group consisting of: a ballistic protection article, a helmet, a sheet or panel, such as a vehicle or blast protection panel, body armor, and cargo containers.

### Protection from Lasers

It is another aspect of the present disclosure that melanin, Hephamelanin, and composite materials as disclosed herein including melanin can be used for shielding from lasers.

### Thermal Properties

Melanin's ability to resist degradation by extreme heat, e.g. >500° C., was reported by Deziderio (Deziderio, 2004). Melanin's ability to resist degradation by extreme cold (slightly above absolute zero) was reported by (Yang and Anderson, 1986). The present disclosure includes the discovery that melanin can be used alone, or in composites with other materials such as metals and polymers, to resist destruction by high heat or temperature, for shielding, armor, and aerospace applications such as airplane and space vehicle construction parts.

### Chemical Properties

The ability of melanin to resist degradation by chemicals of all types, including strong acids (such as hydrochloric acid) and bases (such as sodium hydroxide), was reviewed by (Prota, 1992). The present disclosure includes the discovery that melanin can be used alone, or in composites with other materials such as metals and polymers, to resist destruction by chemicals including strong acids and strong bases, for shielding, armor, and aerospace applications such as airplane and space vehicle construction parts.

### Protection from Radiation

It has been reported that melanin absorbs beta particles, gamma rays, X-rays, infrared, visible, ultraviolet, the remainder of the electromagnetic spectrum, and combinations thereof.

The present disclosure includes the discovery that Hephamelanin, melanin and composite materials incorporating melanin can be used alone, or in composites with other materials such as lead and polymers, to absorb and prevent destruction by radiation, e.g., for shielding, armor, and aerospace applications such as airplane and space vehicle construction parts.

The present disclosure includes the discovery that radioprotectant/radiomitigation hybrid compositions, such as that melanin, Hephamelanin, and composite materials as disclosed herein can be used alone, or in composites with other materials for:
a. shielding of radiation from sources like uranium and radium.
b. to degrade, encapsulate and shield from living and non-living radioactive particles in sizes from nanometers to millimeters.
c. to shield personnel and equipment from radiation from depleted uranium used in weaponry or armor.

The present disclosure includes the discovery that that melanin, Hephamelanin, and composite materials as disclosed herein can be used alone, or in composites with other materials not only by covering a human or other organism by that melanin, Hephamelanin, and composite materials as disclosed herein, alone or in mixture with other materials: It can be accomplished by ingestion, injection, or other internal administration of these compounds or composites.

Furthermore, melanin, Hephamelanin, and composite materials as disclosed herein, can be used to mitigate the destructive biological effects of radiation, even if the radiation has been absorbed. For instance, radiation creates free radicals in biological tissues which creates great damage in the hematopoietic and gastrointestinal systems. That melanin, Hephamelanin, and composite materials as disclosed herein is known to absorb such free radicals and mitigate such damage.

### Protection from Adherence

The present disclosure includes the discovery that Hephamelanin, melanin and composite materials incorporating melanin can be used alone, or in composites with other materials to form shielding from adherent substances for applications where Teflon and similar materials are currently used.

### Protection from Sensors

The present disclosure includes the discovery that melanin, Hephamelanin, and composite materials as disclosed herein, can be used alone, or in composites with other materials to form shielding from electromagnetic, sound, ultrasound, and radar sensors.

### Use in Armor and Aerospace

Melanin has been reported to be hard (Majerus, 1998) and to resist abrasion (Majerus, 1998; Moses et al., 2006) The present disclosure includes the discovery that melanin can be used alone, or in composites with other materials to form body armor, vehicle armor, and other applications, including aerospace use, where desirable characteristics include hardness, resistance to abrasion, resistance to indentation, resistance to cutting, flexibility, shock absorption, and sound and ultrasound absorption.

### Electrical Properties

The present disclosure includes the discovery that that melanin, Hephamelanin, and composite materials as disclosed herein, can be used alone, or in composites with other materials, in harsh environments such as the vacuum and extreme cold of space where the following listed properties are desirable or necessary:
Photoconductivity (when light is shined on it, electricity flows),
Semiconductor properties,
Electricity conduction, and
Paramagnetism (Nordlund, 2006).

### Binding to Metals and Radioactive Substances

It has been reported that that melanin, Hephamelanin, and composite materials as disclosed herein binds to metals and radioactive substances (Bruenger et al., 1967) (Fogarty and Tobin, 1996) (Kasatna et al, 2003) (Taylor et al., 1964). The present disclosure includes the discovery that melanin can be used alone, or in composites with other materials to form shielding and armor and for aerospace applications, specifically because it naturally binds to a wide range of metals and to radioactive substances.

### Binder

Binders are useful in fabricating materials from non or loosely assembled matter. For example, binders enable two or more surfaces to become united. In certain embodiments, non-melanin material may be included in the compositions and methods of the disclosure and may be a binder. In exemplary embodiments, any adhesive material, such as phenolic resins, ureaformaldehyde resins, melamine formaldehyde resins, hyde glue, aminoplast resins, epoxy resins, acrylate resins, latexes, polyester resins, urethane resins, and mixtures thereof may be used as a binder. Suitable binders include glue, varnish, epoxy resins, phenolic resins, polyurethane resins. In exemplary embodiments, the binder may be, for example, glue, which may be selected from the group consisting of Clear Weld, LOCTITE® Heavy Duty Epoxy, LOCTITE® Epoxy Metal/Concrete, LOCTITE INSTANT-MIX®, LOCTITE®, LOCTITE® BULLDOG, LOCTITE® PL Marine Adhesive Sealant, E6000®, (E6000 STITCHLESS®, E6000 EXTREME TACK®, E6000 FABRI-FUSE®, PRO-POXY® 20, TITEBOND III®, TITEBOND III ULTIMATE WOOD GLUE®, FIBER FIX SUPER TAPE, ELMER'S SCHOOL GLUE NATURALS®, ELMER'S GLUE-ALL®, Elmer's Multi Purpose All Glue, KRAZY GLUE®, LIQUID NAILS®, PRODUTY® HEAVY DUTY CONSTRUCTION ADHESIVE, Firmo Liquid, Welbond Universal Adhesive, and combinations thereof.

Thermally curable resins suitable for use in accordance with the compositions and methods of the disclosure are preferably selected from the group consisting of phenolic resins, urea formaldehyde resins, melamine-formaldehyde resins, epoxy resins, acrylate resins, urethane resins, melamine resins, alkyd resins, and polyimide resins, isocyanate, isocyanurate, and combinations thereof. Multifunctional acrylates are preferably selected from trimethylolpropane triacrylate, glycerol triacylate, pentaerythritol triacrylate and methacrylate, pentaerythritol tetraacrylate and methacrylate, dipentaerythritol pentaacrylate, sorbitol triacrylate, and sorbital hexaacrylate.

Thermoplastic binders comprise a variety of polymerized materials such as polyvinyl acetate, polyvinyl butyral, polyvinyl alcohol, and other polyvinyl resins; polystyrene resins; acrylic and methacrylic acid ester resins; cyanoacrylates; and various other synthetic resins such as polyisobutylene polyamides, courmarone-idene products, and silicones.

Suitable functionalized acrylics, alkyds, polyurethanes, polyesters, and epoxies can be obtained from a number of commercial sources. Useful acrylics are sold under the ACRYLOID™ trade name (Rohm & Haas, Co., Pennsylvania); useful epoxy resins are sold under the EPON™ trade name (Resolution Specialty Materials, LLC, Illinois); useful polyester resins are sold under the CYPLEX® trade name (Cytec Industries, New Jersey); and useful vinyl resins are sold under the UCAR™ trade name (The Dow Chemical Company, Michigan).

Illustrative of useful high modulus or rigid binder materials are polycarbonates; polyphenylenesulfides; polyphenylene oxides; polyester carbonates; polyesterimides; polyimides; and thermoset resins such as epoxy resins, phenolic resins, modified phenolic resins, allylic resins, alkyd resins, unsaturated polyesters, aromatic vinylesters as for example the condensation produced of bisphenol A and methacrylic acid diluted in a vinyl aromatic monomer (e.g. styrene or vinyl toluene), urethane resins and amino (melamine and urea) resins. The major criterion is that such material holds the composition together and maintains the geometrical integrity of the composite under the desired use conditions. The binder can be included in the composition in any suitable amount. For example, the binder can be included in an amount from about 5 wt. % to about 100 wt. % by weight (on a solids basis) of the wet composition, such as from about 20 wt. % to about 80 wt. %, from about 30 wt. % to about 70 wt. %, from about 40wt. % to about 60 wt. %, etc.

### REFERENCES

Chen, M., Lv, Z., Qian, F., Wang, Y., Xing, X., Zhou, K., Wang, J., Huang, S., Han, S.-T., Zhou, Y., 2021. Phototunable memories and reconfigurable logic applications based on natural melanin. J Mater Chem C 9, 3569-3577. doi.org/10.1039/d1tc00052g.
Gouda, A., Bobbara, S.R., Reali, M., Santato, C., 2019. Light-assisted melanin-based electrochemical energy storage: physicochemical aspects. J Phys D Appl Phys 53, 043003.doi.org/10.1088/1361-6463/ab508b.
Kim, Y.J., Wu, W., Chun, S.-E., Whitacre, J.F., Bettinger, C.J., 2013. Biologically derived melanin electrodes in aqueous sodium-ion energy storage devices. Proc National Acad Sci 110, 20912-20917. https://doi.org/10.1073/pnas.1314345110.
Kumar, P., Mauro, E.D., Zhang, S., Pezzella, A., Soavi, F., Santato, C., Cicoira, F., 2016. Melanin-based flexible supercapacitors. J Mater Chem C 4, 9516-9525. doi.org/10.1039/c6tc03739a.
Li, H. et al. Evaluation of temperature dependent electrical properties for hydrated natural melanins Mol. Biol. Cell 2014 25:P1520.
   Meredith, P. and Sarna, T. 2006 The physical and chemical properties of eumelanin. Pigment Cell Res. 19; 572-594.
McGinness, J.E. 1982 Electrical Energy Storage. U.S. Pat. No. 4,366,216 Issued Dec. 28, 1982.
Qaid, S.A.S., Alzayed, N.S., Shahabuddin, M., Al-Asbahi, B.A., Abuassaj, E.M., Ahmed, A.A.A., 2022. The effect of sintering conditions on the superconducting properties of melanin doped MgB2. J Magn Magn Mater 552, 169213. https://doi.org/10.1016/j.jmmm.2022.169213 Sheliakina, M., Mostert, A.B., Meredith, P., 2018. An all-solid-state biocompatible ion-to-electron transducer for bioelectronics. Mater Horizons 5, 256-263. doi.org/10.1039/c7mh00831g.

The invention will be illustrated in more detail with reference to the following Examples, but it should be understood that the present invention is not deemed to be limited thereto.

### EXAMPLES

### Example 1

### Method for Formulation of Melanin and Derivatives for Superconductive and Other Properties

An example of the basic material is melanin. Either synthetic melanin (made by organic or water-based synthesis) or natural melanin may be used. The following example applies to natural melanin from cuttlefish.

The natural melanin may be dispersed in, for example, water, deionized water, distilled water, and/or combinations thereof, and then centrifuged at about 10,000 g to 14,000 g to remove some non-melanin proteins found in the raw natural material. The supernatant is decanted, and the procedure is repeated so that the melanin has been washed a total of about seven times. It is then placed in a vacuum furnace heated for at least 1.5 hours at temperatures ranging from about 200° C. to about 850° C. Instead of a vacuum surrounding the melanin when it is heated, it can be surrounded by a noble gas. The inventor calls the resulting formulation Hephamelanin (named after Hephaestus, the Greek god of blacksmiths and fire.)

The inventor has discovered that Hephamelanin is superconducting. It can preferably be used at temperatures ranging from slightly above absolute zero to room temperature. Most preferably it will be used in the range of liquid nitrogen temperatures (e.g. about 77° Kelvin), or in the range of the temperature of outer space, which is about 4° Kelvin. This temperature is most common in interstellar space, where the light of local stars does not create heat.

The inventor has discovered that Hephamelanin also absorbs radiation, including the entire electromagnetic spectrum. It is remarkably hard and resists abrasion like a metal or synthetic polymer.

Hephamelanin variants include starting with a synthetic or natural melanin and doping it with metal ions such as bismuth, copper, silver, etc. or other ions, which enhance its properties for various applications.

The inventor has discovered that Hephamelanin is as strong as metals and hard polymers, has superior abrasion resistance, heat resistance, tensile strength, and other highly desirable physical properties. It can be used in armor or shielding. It will protect against attack by physical agents and by radiation. It will absorb or reflect most types of radiation, including the entire electromagnetic spectrum. The energy absorbed from the radiation can be transduced to electricity.

While the invention has been described in detail and with reference to specific examples thereof, it will be apparent to one skilled in the art that various changes and modifications can be made therein without departing from the spirit and scope thereof.

What is claimed is:

1. A Hephamelanin material made by a process comprising:
i) dispersing a basic material selected from the group consisting of natural melanin, synthetic melanin, and combinations thereof, in water;
ii) centrifuging the basic material;
iii) repeating step i) and ii) at least about 3 times, to form a purified basic material;
iv) placing the purified basic material in a vacuum furnace; and
v) heating the purified basic material for at least 1.5 hours at temperatures ranging from about 200° C. to about 850° C.,
thereby forming a Hephamelanin material.

2. A Hephamelanin material made by a process comprising:
i) dispersing a basic material selected from the group consisting of natural melanin, synthetic melanin, and combinations thereof in water;
ii) centrifuging the basic material;
iii) repeating step i) and ii) at least about 5 times, to form a purified basic material;
iv) placing the purified basic material in a furnace;
v) surrounding the purified basic material with at least one noble gas; and
vi) heating the purified basic material for at least 1.5 hours at temperatures ranging from about 200° C. to about 850° C.,
thereby forming a Hephamelanin material.

3. The Hephamelanin material of claim 2, wherein the noble gas is selected from the group consisting of helium (He), neon (Ne), argon (Ar), krypton (Kr), xenon (Xe), radon (Rn), oganesson (Og), and combinations thereof.

4. The Hephamelanin material of claim 1 wherein step iii) is repeated at least about 4 times, at least about 5 times, at least about 6 times, at least about 7times, at least about 8 times, at least about 9 times, or at least about 10 times.

5. The Hephamelanin material of claim 1 wherein the Hephamelanin material can absorb types of energy selected from the group consisting of light, heat, radiation, sound waves, pressure waves, vibrations, and combinations thereof.

6. The Hephamelanin material of claim 5 wherein energy absorbed by the Hephamelanin material is transduced to electricity.

7. The Hephamelanin material of claim 5 wherein light absorbed by the Hephamelanin material is converted to electricity by photoconductivity.

8. The Hephamelanin material of claim 5 wherein heat absorbed by the Hephamelanin material is converted to electricity through pyroelectricity.

9. The Hephamelanin material of claim 5 wherein heat absorbed by the Hephamelanin material is converted to electricity through thermoelectricity.

10. The Hephamelanin material of claim 5 wherein pressure absorbed by the Hephamelanin material is converted to electricity through piezoelectricity.

11. The Hephamelanin material of claim 5 wherein sound absorbed by the Hephamelanin material is converted to electricity.

12. The Hephamelanin material of claim 5 wherein radiation particles and waves absorbed by the Hephamelanin material are converted to electricity.

13. The Hephamelanin material of claim 5 wherein the Hephamelanin material absorbs radiation, including the entire electromagnetic spectrum, and can convert this energy into electricity.

14. The Hephamelanin material of claim 5 wherein the Hephamelanin material or its derivatives can transduce input sources of energy into electrical energy and store or output electrical energy.

15. The Hephamelanin material of claim 5 wherein the Hephamelanin material can transmit energy, by superconductivity.

16. The Hephamelanin material of claim 5 wherein the Hephamelanin material or its derivatives can also efficiently store energy.

17. The Hephamelanin material of claim 5 wherein the has been configured to form supercapacitors or batteries.

18-21. (Canceled)

22. A process for forming a Hephamelanin material comprising the steps of:
vii) dispersing a basic material selected from the group consisting of natural melanin, synthetic melanin, and combinations thereof, in a water;
viii) centrifuging the basic material;
ix) repeating step i) and ii) at least about 5 times, to form a purified basic material;
x) placing the purified basic material in a vacuum furnace; and
xi) heating the purified basic material for at least 1.5 hours at temperatures ranging from about 200° C. to about 850° C.,
thereby forming a Hephamelanin material.

23. A process for forming a Hephamelanin material comprising the steps of:
i) Dispersing a basic material selected from the group consisting of natural melanin, synthetic melanin, and combinations thereof, in water;
ii) centrifuging the basic material;
iii) repeating step i) and ii) at least about 5 times, to form a purified basic material;
iv) placing the purified basic material in a furnace;
v) surrounding the purified basic material with at least one noble gas; and
vi) heating the purified basic material for at least 1.5 hours at temperatures ranging from about 200° C. to about 850° C.,
thereby forming a Hephamelanin material.

24. The process for forming a Hephamelanin material of claim 23, wherein the noble gas is selected from the group consisting of helium (He), neon (Ne), argon (Ar), krypton (Kr), xenon (Xe), radon (Rn), oganesson (Og), and combinations thereof.

25. The process for forming a Hephamelanin material of any one of claims 23 to 24 wherein step iii) is repeated at least about 4 times, at least about 5 times, at least about 6 times, at least about 7 times, at least about 8 times, at least about 9 times, or at least about 10 times.

26-59. (canceled)
